(19) United States
(12) Patent Application Publication
(10) Pub. No.: US 2009/0194318 A1
(43) Pub. Date: Aug. 6, 2009

(54) Printed circuit board and method for manufacturing the same

(75) Inventors: Je-Sik Yeon, Seoul (KR); Duck-Young Maeng, Suwon-si (KR); Se-Won Park, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/213,972

(22) Filed: Jun. 26, 2008

(30) Foreign Application Priority Data
Feb. 4, 2008 (KR) 10-2008-0011035

(51) Int. Cl. H01B 13/00; H05K 1/00

(52) U.S. Cl. 174/250; 216/13

(57) ABSTRACT

A printed circuit board and a method for manufacturing the printed circuit board are disclosed. The method for manufacturing a printed circuit board can include forming a circuit pattern over a seed layer that is formed over an insulation layer, pressing the circuit pattern such that the circuit pattern and the seed layer corresponding with the circuit pattern are buried in the insulation layer, and removing the exposed seed layer. This method can prevent undercuts caused by etching in the seeds positioned between the circuit pattern and the insulation layer, and can thereby prevent the circuit pattern from becoming detached. Also, the adhesion between the circuit pattern and the insulation layer can be increased, making it possible to implement a finer circuit pattern over the insulation layer.

### CROSS-REFERENCE TO RELATED APPLICATIONS

This application claims the benefit of Korean Patent Application No. 10-2008-0011035 filed with the Korean Intellectual Property Office on Feb. 4, 2008, the disclosure of which is incorporated herein by reference in its entirety.

### BACKGROUND

1. Technical Field

The present invention relates to a printed circuit board and a method for manufacturing the printed circuit board.

2. Description of the Related Art

In step with the trends towards smaller size and higher efficiency in current electronic devices, there is a demand for narrower linewidths in circuit patterns. Methods used to satisfy this demand include semi-additive processes, which may involve forming a dry film as a plating resist over a seed layer, forming the circuit pattern by an electroplating process, and then removing the seed layer.

In a semi-additive process, however, when the seed layer formed by electroless plating is removed by etching, the rate at which the seed layer is etched may be higher than the rate at which the circuit pattern is etched. This can lead to an undercut, as the seed layer positioned between the circuit pattern and the insulation layer is etched, and can result in the circuit pattern becoming detached.

Thus, there is a need for a method of manufacturing a printed circuit board, with which the occurrence of undercuts may be avoided during the removal of the seed layer in a semi-additive process.

### SUMMARY

An aspect of the invention is to provide a method of manufacturing a printed circuit board that prevents undercuts and thereby prevents the circuit pattern from becoming detached.

Another aspect of the invention is to provide a method of manufacturing a printed circuit board that increases adhesion between the circuit pattern and the insulation layer, to allow finer circuit patterns.

One aspect of the invention provides a method of manufacturing a printed circuit board. The method includes forming a circuit pattern over a seed layer that is formed over an insulation layer, pressing the circuit pattern such that the circuit pattern and the seed layer corresponding with the circuit pattern are buried in the insulation layer, and removing the exposed seed layer.

In certain embodiments, the operation of forming the circuit pattern may be performed by electroplating.

Pressing the circuit pattern can include pressing the circuit pattern such that a portion of the circuit pattern is buried in the insulation layer.

The pressing of the circuit pattern can be performed using a press or a vacuum laminator.

The operation of removing the seed layer may be performed by flash etching.

Another aspect of the invention provides a printed circuit board that includes an insulation layer, a seed buried in the insulation layer, and a circuit pattern formed over the seed such that a portion of the circuit pattern is buried in the insulation layer.

The seed can be formed to envelop the portion of the circuit pattern.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating an embodiment of a method of manufacturing a printed circuit board according to an embodiment of the invention.

FIG. 2, FIG. 3, FIG. 4, and FIG. 5 are cross sectional views each representing a process in a method of manufacturing a printed circuit board according to an embodiment of the invention.

FIG. 6 is a graph comparing the widths of circuit patterns formed by a method of manufacturing a printed circuit board according to an embodiment of the invention with the widths of circuit patterns formed by a method according to the related art.

FIG. 7 is a cross sectional view of a printed circuit board according to another embodiment of the invention.

### DETAILED DESCRIPTION

The printed circuit board and method for manufacturing the printed circuit board according to certain embodiments of the invention will be described below in more detail with reference to the accompanying drawings. Those components that are the same or are in correspondence are rendered the same reference numeral regardless of the figure number, and redundant explanations are omitted.

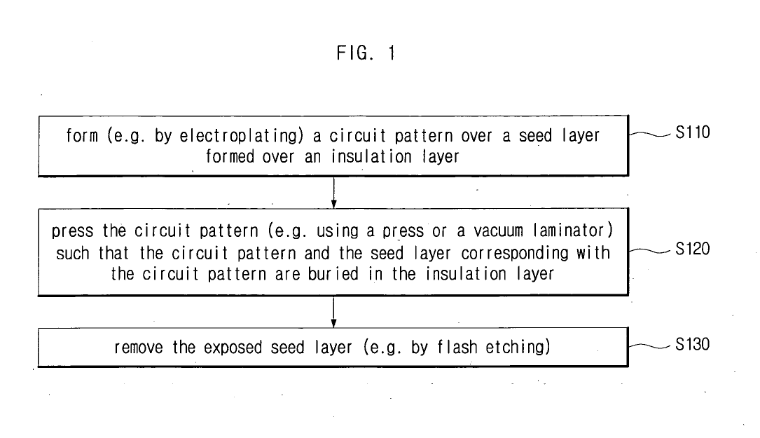

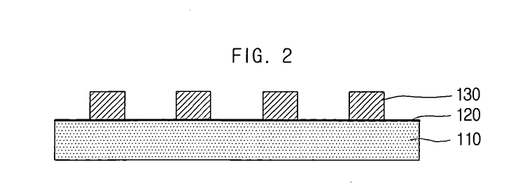

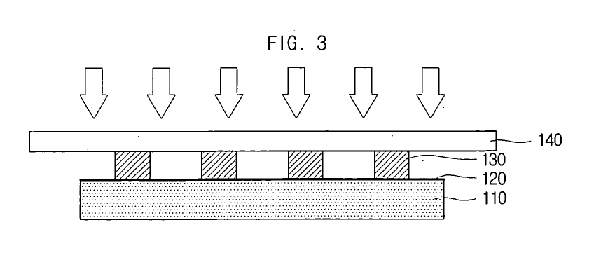

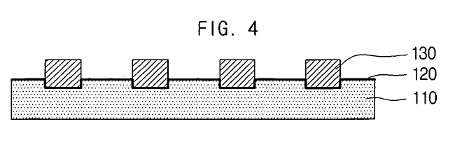

FIG. 1 is a flowchart illustrating an embodiment of a method of manufacturing a printed circuit board according to an embodiment of the invention, while FIG. 2 through FIG. 5 are cross sectional views each representing a process in a method of manufacturing a printed circuit board according to an embodiment of the invention.

In FIGS. 1 to 5, there are illustrated a printed circuit board 100, an insulation layer 110, a seed layer 120, seeds 120′, a circuit pattern 130, 130′, and a press 140.

This embodiment provides a method of manufacturing a printed circuit board 100 that includes forming a circuit pattern 130′ by a semi-additive process. In this method, a circuit pattern 130 and corresponding parts of a seed layer 120 can be pressed and buried into an insulation layer 110 using a press 140 or a vacuum laminator. Thus, when the exposed parts of the seed layer 120 over which the circuit pattern 130 is not formed are removed by flash etching, undercuts caused by etching in the seeds 120′ positioned between the circuit pattern 130 and the insulation layer 110 can be prevented, so that the circuit pattern 130 may be prevented from becoming detached. Also, the adhesion between the circuit pattern 130 and the insulation layer 110 can be increased, making it possible to implement a finer circuit pattern 130′ over the insulation layer 110.

First, as illustrated in FIG. 2, the circuit pattern 130 can be formed over the seed layer 120, which may be formed over the insulation layer 110 (S110). Following the procedures for forming a circuit pattern 130 according to a semi-additive process, the seed layer 120 can be formed over one side of the insulation layer 110 using electroless plating, after which a plating resist layer, such as a dry film, etc., can be formed over the surface of the seed layer 120 excluding those portions where the circuit pattern 130 is to be formed. Then, a conductive material can be plated on using electroplating to form the circuit pattern 130, and afterwards the plating resist layer can be removed.

The layer of plating resist can be formed by stacking a dry film over the surface of the seed layer 120 and removing those portions corresponding to the circuit pattern 130 according to a photolithography process.

Next, as illustrated in FIG. 3 and FIG. 4, the circuit pattern 130 can be pressed, such that the circuit pattern 130 and the seed layer 120 corresponding to the circuit pattern 130 are buried in the insulation layer 110 (S120). That is, the circuit pattern 130 and portions of the seed layer 120 positioned in correspondence with the circuit pattern 130 can be buried into the insulation layer 110 using a press 140 or a vacuum laminator.

Using a press may provide the advantage that the circuit pattern 130 and seed layer 120 can be buried by way of a simple, straightforward process. Conversely, using a vacuum laminator may provide the advantage that the seed layer 120 and circuit pattern 130 can be buried more effectively, since the seed layer 120 and circuit pattern 130 can be pressed into the insulation layer 110 within a vacuum, without being affected by air, etc.

The insulation layer 110 can be in a semi-cured state (e.g. B-stage), so that the circuit pattern 130 and seed layer 120 may be buried in the insulation layer 110 more easily.

With the circuit pattern 130 and the corresponding portions of the seed layer 120 buried in the insulation layer 110, the area of contact between the circuit pattern 130 and the seeds 120′ may be increased. This can prevent undercuts caused by a difference in etching rate between the seed layer 120 and the circuit pattern 130 during the application of flash etching to the seed layer 120, and consequently the adhesion between the circuit pattern 130 and the insulation layer 110 can be increased, so that the circuit pattern 130 can be prevented from becoming attached. As a result, the defect rate can be dramatically reduced in the process for manufacturing a printed circuit board 100, and the circuit pattern 130 can be formed with a finer linewidth.

As illustrated in FIG. 4, the circuit pattern 130 and the corresponding portions of the seed layer 120 can be pressed such-that only a portion of the circuit pattern 130 is buried, for example, to a depth of 2 to 5 micrometers. In this way, undercuts can be avoided as described above without significantly altering the overall thickness of the printed circuit board. As such, it may not be necessary to additionally modify the designs of other external devices, and there may be further benefits in terms of cost effectiveness.

Of course, besides pressing the circuit pattern 130 such that only a portion of the circuit pattern 130 is buried in the insulation layer 110 as illustrated in FIG. 4, it is also possible to press the circuit pattern 130 such that the circuit pattern 130 is completely buried in the insulation layer 110. In such cases, the circuit pattern 130 may not protrude outwards above the surface of the insulation layer 110, whereby the overall thickness of the printed circuit board 100 can be decreased and the bending strength of the printed circuit board 100 can be improved.

Next, as illustrated in FIG. 5, the exposed seed layer 120 can be removed (S130). That is, portions of the seed layer 120, over which the circuit pattern 130 is not formed, and which are hence exposed, can be removed by flash etching to leave only the seeds 120′. At the same time, a portion may also be removed from the surface of the circuit pattern 130, whereby the circuit pattern 130′ can be formed free of short-circuiting.

As the circuit pattern 130 and the corresponding seed layer 120 are buried in the insulation layer 110 as described above, the area by which the circuit pattern 130 and the seeds 120′ contact each other can be increased, and the seeds 120′ can be protected inside the insulation layer 110. Thus, even if the etching rate of the seed layer 120 is higher than the etching rate of the circuit pattern 130, the occurrence of undercuts, in which parts of the seeds 120′ are removed by the etchant, can be avoided, and the adhesion between the circuit pattern 130′ and the insulation layer 110 can be improved.

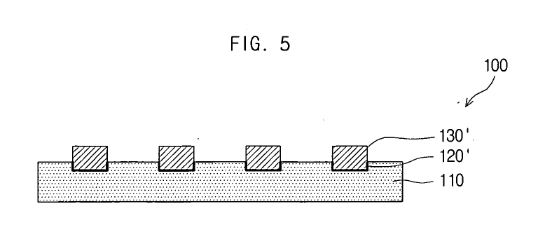

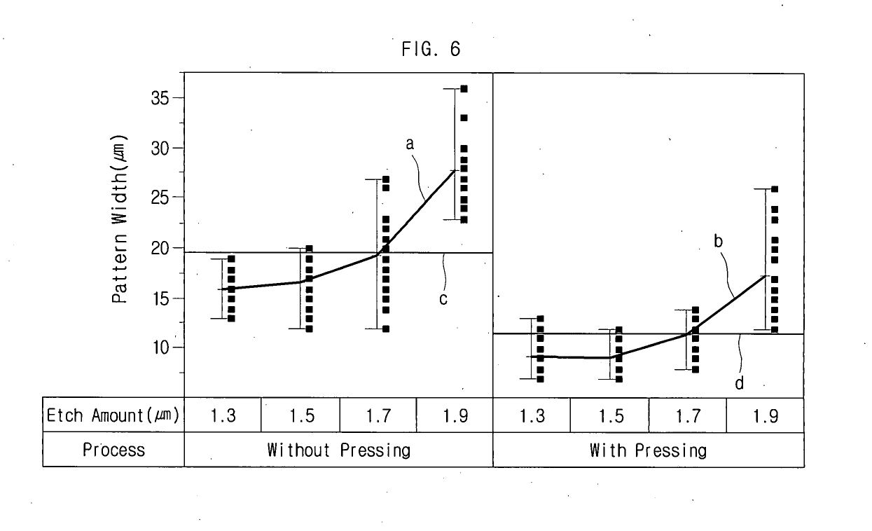

FIG. 6 is a graph comparing the widths of circuit patterns formed by a method of manufacturing a printed circuit board according to an embodiment of the invention with the widths of circuit patterns formed by a method according to the related art. With reference to FIG. 6, the following description will compare those circuit patterns formed according to the related art with those circuit patterns 130′ formed according to an embodiment of the invention. The graph in FIG. 6 displays measurement results for the widths of circuit patterns 130′ after applying flash etching. The results were obtained using a test substrate, in which circuit patterns 130 of various widths were formed over a seed layer 120.

To obtain the test results for an embodiment of the invention, the circuit patterns 130 were pressed using a vacuum laminator. The circuit patterns 130 were subjected to a first round of pressing for 20 minutes at 180° C. and 0.95 MPa while maintaining a vacuum for 1 minute, and then were subjected to a second round of pressing for 30 seconds at 120° C. and 0.75 MPa.

Also, the amount of etching for the flash etching was varied to 1.3,. 1.5, 1.7, and 1.9 micrometers, and the results were compared to those for the related art, in which there was no pressing applied to the circuit pattern 130 and seed layer 120.

As represented in FIG. 6, when the etching amount is the same at 1.3, 1.5, 1.7, and 1.9 micrometers, it is observed that finer circuit patterns 130′ remained on the test substrate for those cases where the circuit pattern 130 and seed layer 120 are pressed according to an embodiment of the invention, compared to cases where there is no pressing according to the related art. This- is clearly shown by the lines (a, b) connecting the average values for the widths of the remaining circuit patterns 130′ for each etching amount, as well as by the lines (c, d) showing the overall average regardless of the etching amount.

Thus, it can be seen that in cases where a pressing process is performed as in an embodiment of the invention, the adhesion between the circuit pattern 130 and the insulation layer 110 may be increased, so that the circuit pattern 130′ can be formed to finer linewidths.

A description will now be provided on a printed circuit board according to an embodiment of the invention.

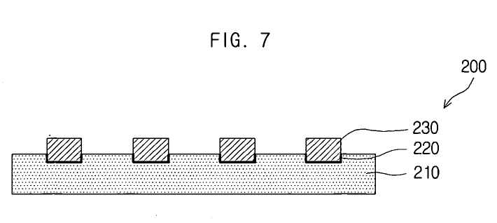

FIG. 7 is a cross sectional view of a printed circuit board according to another embodiment of the invention. In FIG. 7, there are illustrated a printed circuit board 200, an insulation layer 210, seeds 220, and a circuit pattern 230.

This embodiment provides a printed circuit board 200, in which portions of the circuit pattern 230 and the seeds 220 may be buried in the insulation layer 210, so that the area by which the seeds 220 contact the circuit pattern 230 may be increased, making it possible to form a finer circuit pattern 230.

The seeds 220 can be buried in areas of the insulation layer 210 where the circuit pattern 230 is to be formed, and the circuit pattern 230 can be formed over the seeds 220 with portions of the circuit pattern 230 buried in the insulation layer 210, for example to a depth of 2 to 5 micrometers. Here, the seeds 220 may be formed to envelop the buried portions of the circuit pattern 230.

The seeds 220 and the circuit pattern 230 can be formed by a semi-additive process. As this has already been described in detail with respect to an embodiment of the invention for a method of manufacturing a printed circuit board 200, only a brief description of the process will be provided below.

A seed layer 120 (FIG. 2) can be formed by electroless plating over a surface of an insulation layer 210, a circuit pattern 130 (FIG. 2) can be formed by electroplating, and the plating resist layer can be removed. Then, the circuit pattern 130 (FIG. 3) and the corresponding seed layer 120 (FIG. 3) can be pressed using a press, etc., and the exposed seed layer 120 (FIG. 4) can be removed by flash etching, to form seeds 220 buried in the insulation layer 210 and a circuit pattern 230 having a portion buried in the insulation layer 210.

As the seeds 220 and the portion of the circuit pattern 230 are buried, undercuts that may occur due to the flash etching can be avoided, and the adhesion between the insulation layer 210 and the circuit pattern 230 can be increased. Since undercuts can be prevented without significantly altering the overall thickness of the printed circuit board, it may not be necessary to additionally modify the designs of other external devices, for further benefits in terms of cost effectiveness.

Also, as the seeds 220 may be formed to envelop the buried portions of the circuit pattern 230, the contact area between the seeds 220 and the circuit pattern 230 may be further increased, and the adhesion between the insulation layer 210 and the circuit pattern 230 may be further increased accordingly. As a result, defects involving the detaching of the circuit pattern 230 can be prevented, and the circuit pattern 230 can be formed over the insulation layer 210 in finer linewidths.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention. Many embodiments other than those set forth above can be found in the appended claims.

What is claimed is:

1. A method of manufacturing a printed circuit board, the method comprising:
forming a circuit pattern over a seed layer, the seed layer formed over an insulation layer;
pressing the circuit pattern such that the circuit pattern and the seed layer corresponding with the circuit pattern are buried in the insulation layer; and
removing the exposed seed layer.

2. The method of claim 1, wherein the forming of the circuit pattern is performed by electroplating.

3. The method of claim 1, wherein the pressing of the circuit pattern includes:
pressing the circuit pattern such that a portion of the circuit pattern is buried in the insulation layer.

4. The method of claim 1, wherein the pressing of the circuit pattern is performed using a press or a vacuum laminator.

5. The method of claim 1, wherein the removing of the seed- layer is performed by flash etching.

6. A printed circuit board comprising:
an insulation layer;
a seed buried in the insulation layer; and
a circuit pattern formed over the seed such that a portion of the circuit pattern is buried in the insulation layer.

7. The printed circuit board of claim 6, wherein the seed envelops the portion of the circuit pattern.
